(19) United States
(12) Patent Application Publication
(10) Pub. No.: US 2024/0162340 A1
(43) Pub. Date: May 16, 2024

(54) SEMICONDUCTOR DEVICE AND MANUFACTURING METHOD

(71) Applicant: Fujitsu Limited, Kawasaki-shi (JP)

(72) Inventors: Yusuke KUMAZAKI, Atsugi (JP); Shirou OZAKI, Yamato (JP); Naoya OKAMOTO, Isehara (JP); Yasuhiro NAKASHA, Hadano (JP); Toshihiro OHKI, Hadano (JP)

(73) Assignee: Fujitsu Limited, Kawasaki-shi (JP)

(21) Appl. No.: 18/469,177

(22) Filed: Sep. 18, 2023

(30) Foreign Application Priority Data
Nov. 15, 2022 (JP) 2022-182496

(51) Int. Cl. H01L 29/778; H01L 29/06; H01L 29/66

(52) U.S. Cl. CPC H01L 29/7786; H01L 29/0603; H01L 29/66431

(57) ABSTRACT

A semiconductor device includes a semiconductor layer including an electron transit layer and an electron supply layer; a gate electrode, a source electrode and a drain electrode, the gate electrode, the source electrode and the drain electrode being disposed on the semiconductor layer; and a metal film connected to the gate electrode, wherein the semiconductor layer includes an active region, and an inactive region surrounding the active region in plan view, wherein the gate electrode includes, in plan view, a first region overlapping the active region, and two second regions having the first region interposed therebetween, the two second regions both overlapping the inactive region, and wherein the metal film contacts the two second regions.

### CROSS-REFERENCE TO RELATED APPLICATIONS

The present application is based upon and claims the benefit of priority from the prior Japanese Patent Application No. 2022-182496 filed on Nov. 15, 2022, with the Japanese Patent Office, the entire contents of which are incorporated herein by reference.

### FIELD

The disclosure discussed herein relates to a semiconductor device and a manufacturing method.

### BACKGROUND

High electron mobility transistors (HEMTs) have been used extensively in amplifiers for frequency bands such as microwaves or millimeter waves, and signal processing circuits in optical communications. In HEMTs used in high frequency bands, the effect of the electrical resistance of the gate electrode on the high frequency signal is likely to be significant. Therefore, a HEMT with a lower gate electrode and an upper gate electrode has been proposed for the purpose of achieving both high frequency characteristics and mechanical strength (Patent Document 1).

### RELATED-ART DOCUMENTS

### Patent Documents

[Patent document 1] Japanese Laid-Open Patent Application No. 2018-182057
[Patent document 2] Japanese Laid-Open Patent Application No. 2004-95637
[Patent document 3] Japanese Laid-Open Patent Application No. 2000-353708

### SUMMARY

According to an aspect of the present disclosure, a semiconductor device includes
a semiconductor layer including an electron transit layer and an electron supply layer;
a gate electrode, a source electrode, and a drain electrode, the gate electrode, the source electrode, and the drain electrode being disposed on the semiconductor layer; and
a metal film connected to the gate electrode,
wherein the semiconductor layer includes an active region, and an inactive region surrounding the active region in plan view,
wherein the gate electrode includes, in plan view, a first region overlapping the active region, and two second regions having the first region interposed therebetween, the two second regions both overlapping the inactive region, and
wherein the metal film contacts the two second regions.

The object and advantages of the embodiment will be realized and attained by means of the elements and combinations particularly pointed out in the claims. It is to be understood that both the foregoing general description and the following detailed description are exemplary and explanatory and are not restrictive of the invention, as claimed.

### BRIEF DESCRIPTION OF DRAWINGS

FIG. 1 is a diagram illustrating a layout of an electrode and a metal film in a semiconductor device according to a first embodiment;

FIG. 2 is a cross-sectional view (part 1) illustrating the semiconductor device according to the first embodiment;

FIG. 3 is a cross-sectional view (part 2) illustrating the semiconductor device according to the first embodiment;

FIG. 4 is a cross-sectional view (part 1) illustrating a method of manufacturing a semiconductor device according to the first embodiment;

FIG. 5 is a cross-sectional view (part 2) illustrating the method of manufacturing a semiconductor device according to the first embodiment;

FIG. 6 is a cross-sectional view (part 3) illustrating the method of manufacturing a semiconductor device according to the first embodiment;

FIG. 7 is a cross-sectional view (part 4) illustrating the method of manufacturing a semiconductor device according to the first embodiment;

FIG. 8 is a cross-sectional view (part 5) illustrating the method of manufacturing a semiconductor device according to the first embodiment;

FIG. 9 is a cross-sectional view (part 6) illustrating the method of manufacturing a semiconductor device according to the first embodiment;

FIG. 10 is a cross-sectional view (part 7) illustrating the method of manufacturing a semiconductor device according to the first embodiment;

FIG. 11 is a cross-sectional view (part 8) illustrating the method of manufacturing a semiconductor device according to the first embodiment;

FIG. 12 is a cross-sectional view (part 9) illustrating the method of manufacturing a semiconductor device according to the first embodiment;

FIG. 13 is a cross-sectional view (part 10) illustrating the method of manufacturing a semiconductor device according to the first embodiment;

FIG. 14 is a cross-sectional view (part 11) illustrating the method of manufacturing a semiconductor device according to the first embodiment;

FIG. 15 is a cross-sectional view (part 12) illustrating the method of manufacturing a semiconductor device according to the first embodiment;

FIG. 16 is a cross-sectional view (part 13) illustrating the method of manufacturing a semiconductor device according to the first embodiment;

FIG. 17 is a cross-sectional view (part 14) illustrating the method of manufacturing a semiconductor device according to the first embodiment;

FIG. 18 is a cross-sectional view (part 15) illustrating the method of manufacturing a semiconductor device according to the first embodiment;

FIG. 19 is a cross-sectional view (part 16) illustrating the method of manufacturing a semiconductor device according to the first embodiment; and

FIG. 20 is a diagram illustrating a layout of an electrode and a metal film in a semiconductor device according to a second embodiment.

### DESCRIPTION OF EMBODIMENTS

The HEMT described in Patent Document 1 requires an opening with a large aspect ratio for the upper gate electrode in order to reduce parasitic capacitances between the upper gate electrode and the source and drain electrodes. It may be extremely difficult to manufacture such an opening with a large aspect ratio with high precision in practice. In particular, in HEMTs used in the sub-terahertz band, it may be particularly difficult to form an opening with a large aspect ratio because the gate length is as small as 100 nm or less to reduce parasitic capacitance and the distance between the source and drain electrodes is also small.

Thus, it is desirable to provide a semiconductor device capable of reducing the adverse effect of the electrical resistance of the gate electrode on the high-frequency signals, and a method of manufacturing such a semiconductor device.

Embodiments of the present disclosure will be described in detail below with reference to the accompanying drawings. In the present specification and drawings, components having substantially identical functional configurations may be omitted from duplicate descriptions by assigning identical symbols. In the present specification and drawings, an X1-X2 direction, an Y1-Y2 direction, and a Z1-Z2 direction are mutually orthogonal. The plane including the X1-X2 direction and the Y1-Y2 direction is defined as an XY plane, the plane including the Y1-Y2 direction and the Z1-Z2 direction is defined as a YZ plane, and the plane including the Z1-Z2 direction and the X1-X2 direction is defined as a ZX plane. For convenience, the Z1 direction is defined as the upward direction and the Z2 direction is defined as the downward direction. In addition, in the present disclosure, the term “plan view” refers to viewing an object from the Z1 side.

### First Embodiment

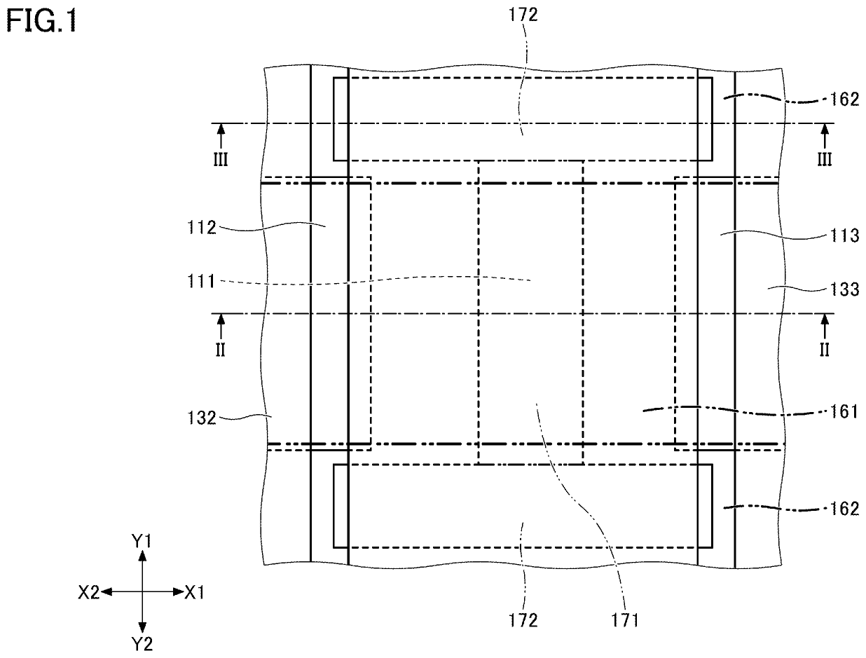

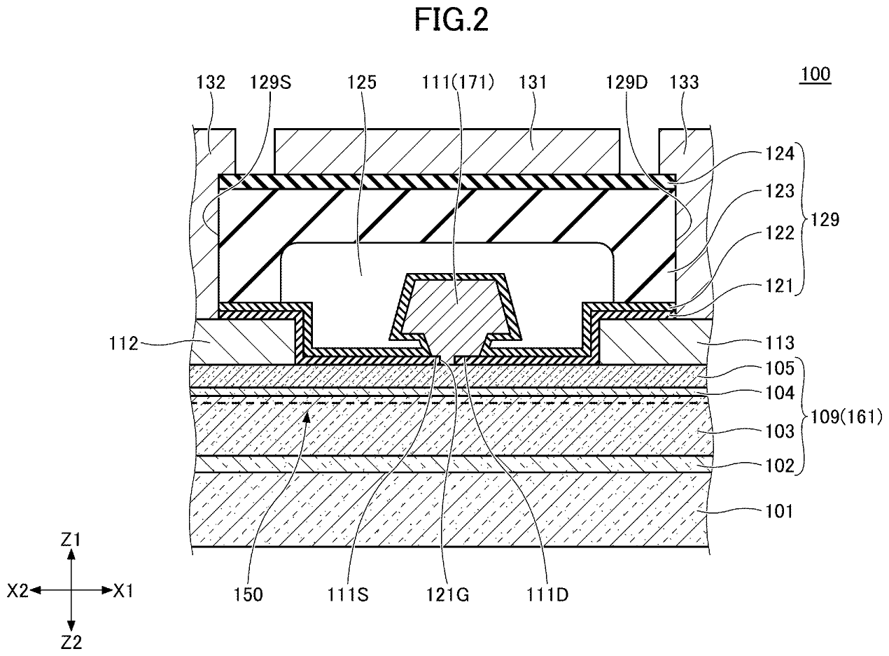

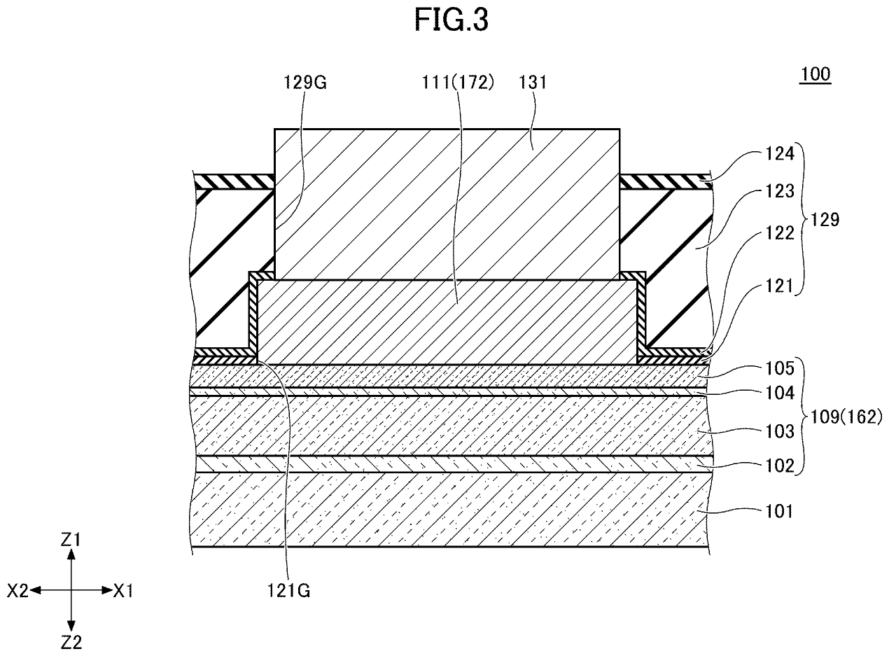

A first embodiment will be described. The first embodiment relates to a semiconductor device including a high electron mobility transistor (HEMT). FIG. 1 is a diagram illustrating a layout of an electrode and a metal film in the semiconductor device according to the first embodiment. FIGS. 2 and 3 are cross-sectional views illustrating the semiconductor device according to the first embodiment. FIG. 2 corresponds to the cross-sectional view along a line II-II in FIG. 1. FIG. 3 corresponds to the cross-sectional view along a line in FIG. 1.

As illustrated in FIGS. 1 to 3, the semiconductor device 100 according to the first embodiment includes a substrate 101 and a semiconductor layer 109 disposed on the substrate 101. The semiconductor layer 109 includes an initial layer 102, an electron transit layer 103, a spacer layer 104, and an electron supply layer 105. The initial layer 102 is formed on the substrate 101. The electron transit layer 103 is formed on the initial layer 102. The spacer layer 104 is formed on the electron transit layer 103. The electron supply layer 105 is formed on the spacer layer 104.

The substrate 101 is, for example, a SiC substrate, a Si substrate, a sapphire substrate, a GaN substrate, an AlN substrate or a diamond substrate. The initial layer 102 is, for example, an AlN layer, a GaN layer, or an AlGaN layer. The initial layer 102 may have a stacked structure containing two or more types of AlN, GaN, or AlGaN layers. The electron transit layer 103 is, for example, a non-doped GaN layer that is not intentionally doped. The spacer layer 104 is, for example, an AlN layer, or an AlGaN layer. The electron supply layer 105 is, for example, an AlGaN layer, an InAlN layer, an InAlGaN layer, an AlN layer, or a ScAlN layer.

The semiconductor layer 109 includes an active region 161 and an inactive region 162 surrounding the active region 161 in plan view. As illustrated in FIG. 2, in the active region 161, a two-dimensional electron gas (2DEG) 150 exists near the interface of the electron transit layer 103 with the spacer layer 104. On the other hand, as illustrated in FIG. 3, in the inactive region 162, there is no 2DEG 150. The active region 161 is defined by the inactive region 162.

A source electrode 112 and a drain electrode 113 are formed on the semiconductor layer 109 in the active region 161. The source electrode 112 and the drain electrode 113 extend parallel to the Y1-Y2 direction and are aligned in the X1-X2 direction. The source electrode 112 and the drain electrode 113 include, for example, a Ti film with a thickness of 2 nm to 50 nm and an Al film with a thickness of 100 nm to 300 nm above the Ti film, and are in ohmic contact with the semiconductor layer 109. A portion of the source electrode 112 and a portion of the drain electrode 113 may be on the semiconductor layer 109 in an inactive region 162.

On the electron supply layer 105, a passivation film 121 is formed covering the source electrode 112 and the drain electrode 113. The passivation film 121 contains, for example, oxides, nitrides, or oxynitrides of Si, Al, Hf, Zr, or Ta. The passivation film 121 is preferably a SiN film. The passivation film 121 may have a stacked structure containing multiple insulating films of these materials. The thickness of the passivation film 121 is, for example, 2 nm to 100 nm, and preferably approximately 50 nm.

In the passivation film 121, a gate opening 121G is formed between the source electrode 112 and the drain electrode 113 in plan view. A gate electrode 111 is formed on the passivation film 121. The gate electrode 111 extends parallel to the Y1-Y2 direction and is located between the source electrode 112 and the drain electrode 113 in plan view. The gate electrode 111 contacts the electron supply layer 105 through the gate opening 121G. The gate electrode 111 includes, for example, a Ni film with a thickness of 5 nm to 30 nm and an Au film with a thickness of 100 nm to 300 nm above the Ni film.

In plan view, the gate electrode 111 includes a first region 171 overlapping the active region 161, and two second regions 172 having the first region 171 interposed between the two second regions 172 and both overlapping the inactive region 162. In the longitudinal direction (parallel to the Y1-Y2 direction) of the gate electrode 111, the first region 171 is between the two second regions 172. In the direction parallel to the X1-X2 direction, that is, in the direction in which the source electrode 112 and the drain electrode 113 are aligned, the dimension of the first region 171 is smaller than that of the second region 172. The dimension of the second region 172 in the direction parallel to the X1-X2 direction is preferably 2 μm or more. The dimension of the lowest part of the first region 171 in the direction parallel to the X1-X2 direction, i.e., the gate length, is, for example, 100 nm or less.

The gate electrode 111 includes a first surface 111S that contacts the upper surface of the passivation film 121 at a position closer to the source electrode 112 than is the gate opening 121G, and a second surface 111D that contacts the upper surface of the passivation film 121 at a position closer to the drain electrode 113 than is the gate opening 121G. In plan view, the end of the second surface 111D closer to the drain electrode 113 side is farther from the gate opening 121G than the end of the first surface 111S closer to the source electrode 112 side.

An insulating film 122 covering the gate electrode 111 is formed on the passivation film 121. The insulating film 122 contains, for example, oxides, nitrides, or oxynitrides of Si, Al, Hf, Zr, or Ta. The insulating film 122 is preferably a SiN film. The insulating film 122 may have a stacked structure including multiple insulating films of these materials. The thickness of the insulating film 122 is, for example, 2 nm to 100 nm, and preferably approximately 50 nm.

A low permittivity film 123 is formed on the insulating film 122. The low permittivity film 123 is an insulating film whose relative permittivity is 3.0 or less. The material of the low permittivity film 123 is, for example, benzocyclobutene (BCB) or methylsilsesquioxane (MSQ). The relative permittivity of the low permittivity film 123 is preferably 2.5 or less. The thickness of the low permittivity film 123 is, for example, 1500 nm to 2000 nm, and preferably approximately 1900 nm.

A cavity 125 is formed between the insulating film 122 and the low permittivity film 123. The cavity 125 surrounds the gate electrode 111. More specifically, the upper surface of the insulating film 122 faces the cavity 125 around the gate electrode 111. The upper surface of a portion of the insulating film 122 directly contacting the gate electrode 111 is away from the low permittivity film 123. The height of the cavity 125 is between 500 nm and 1000 nm at the greatest extent, and preferably approximately 700 nm.

An insulating film 124 is formed on the low permittivity film 123. The insulating film 124 contains, for example, oxides, nitrides, or oxynitrides of Si, Al, Hf, Zr, or Ta. The insulating film 124 is preferably a SiN film. The insulating film 124 may have a stacked structure including multiple insulating films of these materials. The thickness of the insulating film 124 is, for example, 200 nm to 500 nm, and is preferably approximately 300 nm.

A multilayer insulating film 129 includes the passivation film 121, the insulating film 122, the low permittivity film 123, and the insulating film 124. An opening 129S reaching the source electrode 112, an opening 129D reaching the drain electrode 113, and an opening 129G reaching the gate electrode 111 are formed in the multilayer insulating film 129. The opening 129G reaches the two second regions 172 of the gate electrode 111.

Metal films 131, 132, and 133 are formed on the insulating film 124. The metal film 131 is in direct contact with the gate electrode 111 through the opening 129G. The metal film 131 is in direct contact with the two second regions 172. The metal film 132 is in direct contact with the source electrode 112 through the opening 129S. The metal film 133 is in direct contact with the drain electrode 113 through the opening 129D. The metal films 131, 132, and 133 include, for example, a seed layer and a plating layer on the seed layer. The seed layer includes, for example, a Ti layer, an Au layer, or a Cu layer. The plating layer includes, for example, an Au layer, or a Cu layer. In the cross section perpendicular to the longitudinal direction of the first region 171, the cross-sectional area of the metal film 131 is larger than that of the first region 171 of the gate electrode 111. Also, the electrical resistance of the metal film 131 is lower than that of the first region 171.

The metal film 131 is connected to a gate pad (not illustrated), the metal film 132 is connected to a source pad (not illustrated), and the metal film 133 is connected to a drain pad (not illustrated).

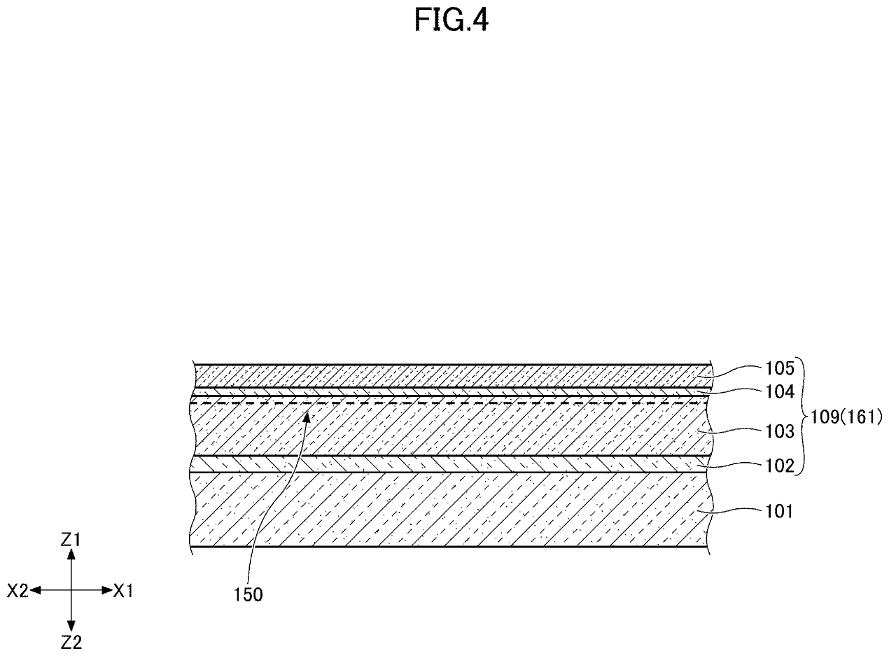

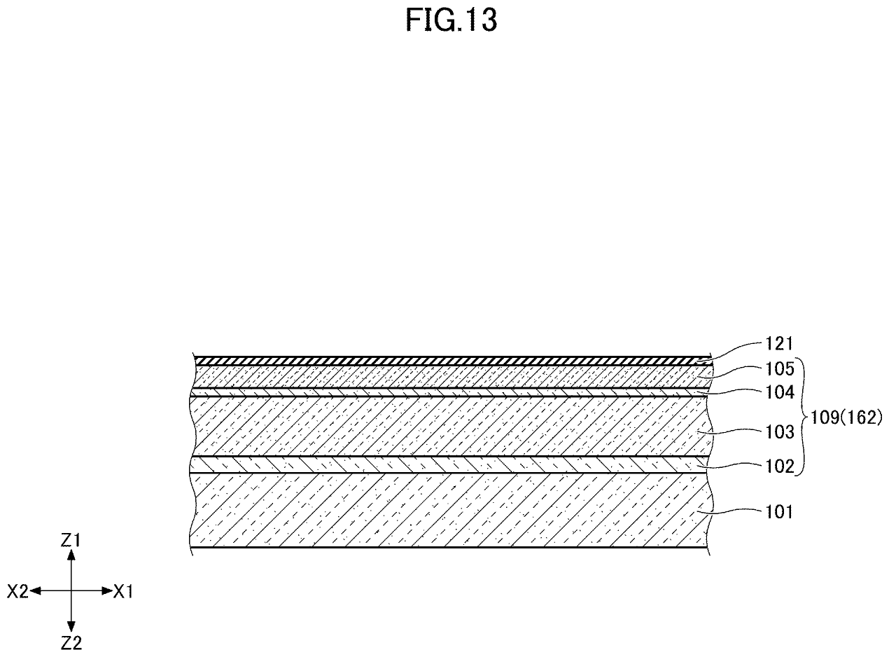

Next, a method of manufacturing the semiconductor device 100 according to the first embodiment will be described. FIGS. 4 to 19 are cross-sectional views illustrating a method of manufacturing the semiconductor device 100 according to the first embodiment. FIGS. 4 to 12 depict changes in the cross section along a line II-II in FIG. 1, and FIGS. 13 to 19 depict changes in the cross section along a line in FIG. 1.

First, as illustrated in FIG. 4, a semiconductor layer 109 is formed on a substrate 101. In the formation of the semiconductor layer 109, an initial layer 102, an electron transit layer 103, a spacer layer 104, and an electron supply layer 105 are formed by, for example, a metal organic chemical vapor deposition (MOCVD) method. A 2DEG 150 is generated near the interface of the electron transit layer 103 with the spacer layer 104.

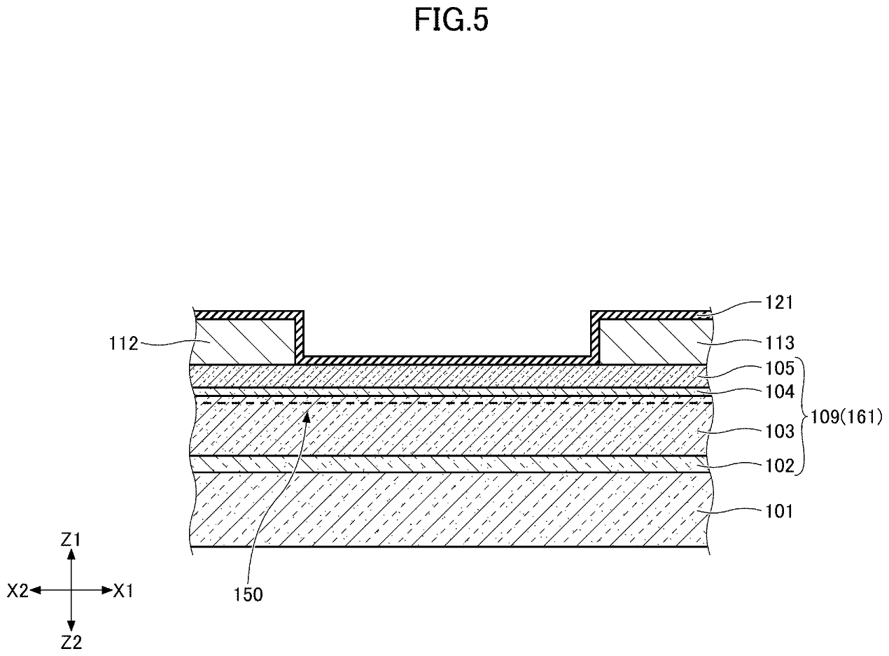

Then, as illustrated in FIG. 5 and FIG. 13, an inactive region 162 is formed in the semiconductor layer 109. In the formation of the inactive region 162, for example, a photoresist pattern to expose the area where the inactive region 162 is to be formed is formed on the semiconductor layer 109, and ion implantation such as Ar implantation is performed using this pattern as a mask. In the inactive region 162, the 2DEG 150 disappears. This pattern may be used as an etching mask for dry etching such as reactive ion etching (RIE) using a chlorine gas. With the formation of the inactive region 162, an active region 161 defined in the inactive region 162 is formed. After the formation of the inactive region 162, the pattern of the resist is removed.

Then, as illustrated in FIG. 5, a source electrode 112 and a drain electrode 113 are formed. The source electrode 112 and the drain electrode 113 can be formed, for example, by a lift-off method. That is, a photoresist pattern is formed to expose the area where the source electrode 112 and the drain electrode 113 are to be formed, a metal film is formed by vapor deposition using this pattern as a growth mask, and this pattern is removed together with the metal film on the pattern. In the formation of the metal film, for example, a Ti film is formed, and an Al film is formed on the Ti film. Then, heat treatment (alloying treatment) is performed at, for example, 500° C. to 650° C. in a nitrogen atmosphere to establish an ohmic contact.

Subsequently, a passivation film 121 is formed on the electron supply layer 105 as illustrated in FIG. 5 and FIG. 13. The passivation film 121 can be formed, for example, by plasma CVD. The passivation film 121 can be formed by atomic layer deposition (ALD) or sputtering.

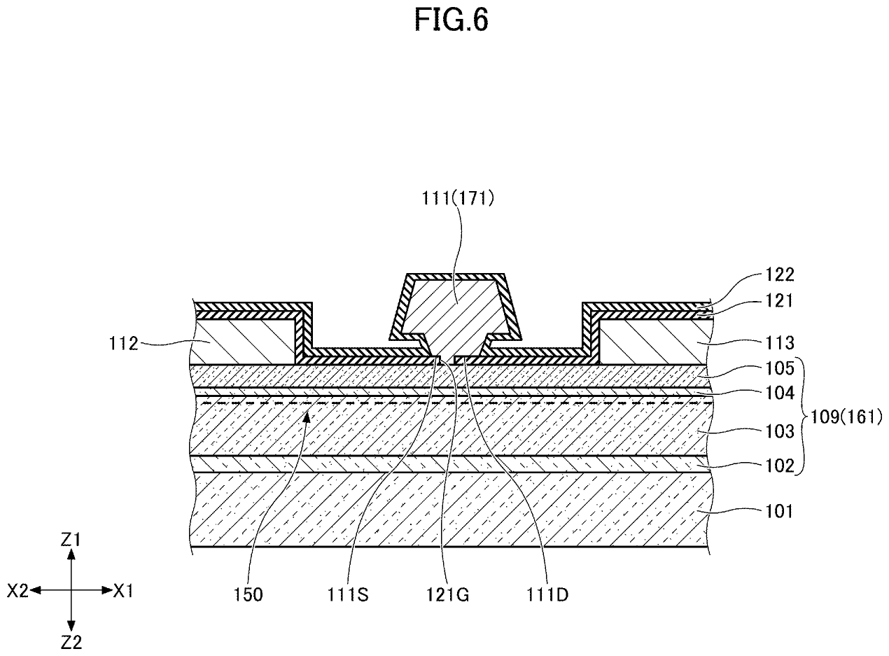

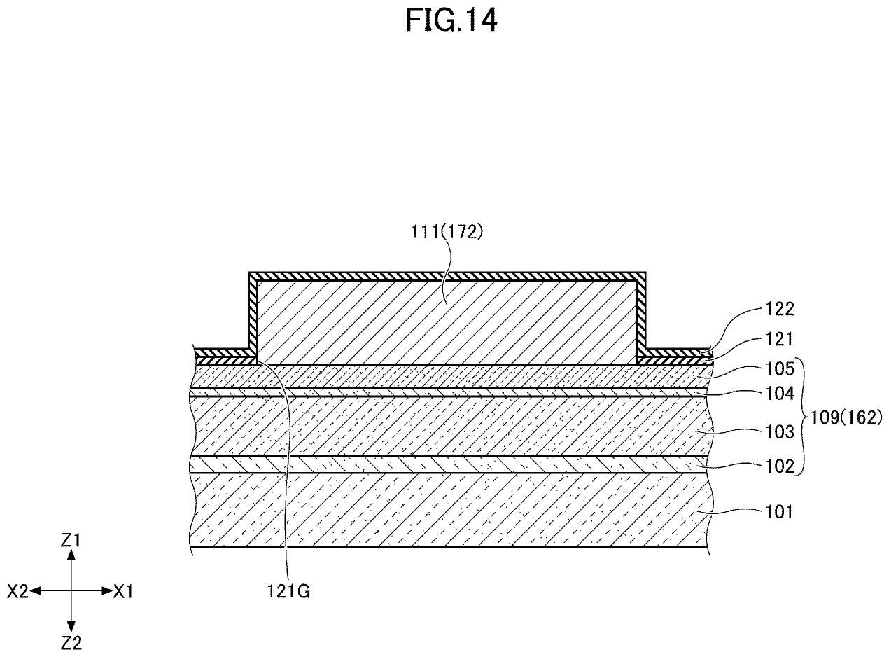

Then, as illustrated in FIG. 6 and FIG. 14, a gate opening 121G is formed in the passivation film 121. In the formation of the gate opening 121G, for example, a photoresist pattern to expose the area where the gate opening 121G is to be formed by photolithography is formed on the passivation film 121, and this pattern is dry-etched using fluorine gas as an etching mask. Instead of dry etching, wet etching using hydrofluoric acid or buffered hydrofluoric acid or the like may be performed.

Then, as illustrated in FIG. 6 and FIG. 14, a gate electrode 111 is formed so that part of the gate electrode 111 is located on the passivation film 121. The gate electrode 111 can be formed, for example, by the lift-off method. That is, a photoresist pattern is formed to expose the area where the gate electrode 111 is to be formed, and a metal film is formed by vapor deposition using this pattern as a growth mask, and this pattern is removed together with the metal film on the pattern. In the formation of the metal film, for example, a Ni film is formed, and an Au film is formed on the Ni film.

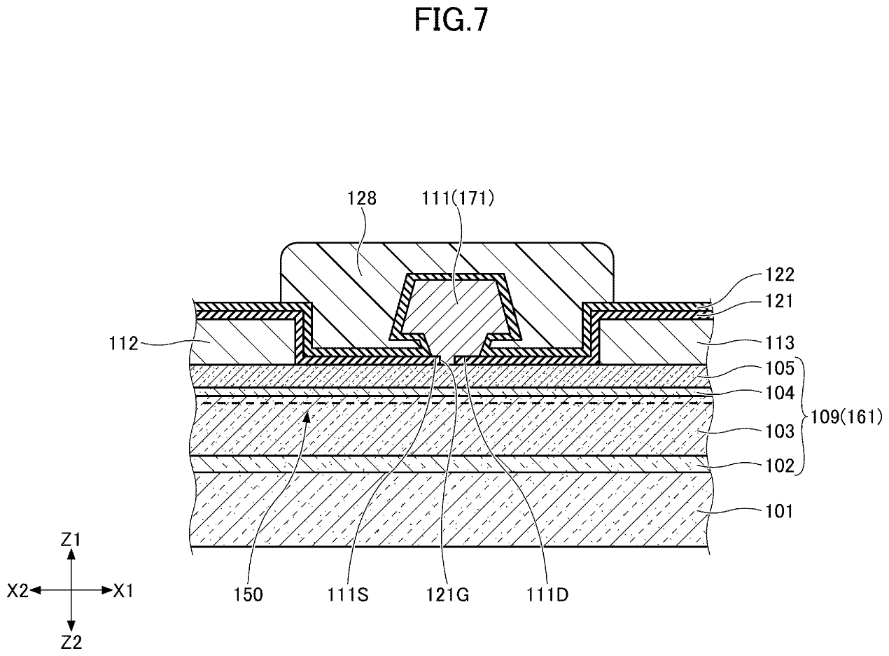

Subsequently, a sacrificial layer 128 is formed to form the cavity 125, as illustrated in FIG. 7. The sacrificial layer 128 is, for example, a polymethylglutarimide (PMGI) layer. In the formation of the sacrificial layer 128, the application of PMGI is performed to remove the PMGI, leaving the portion that forms the cavity 125 to remain.

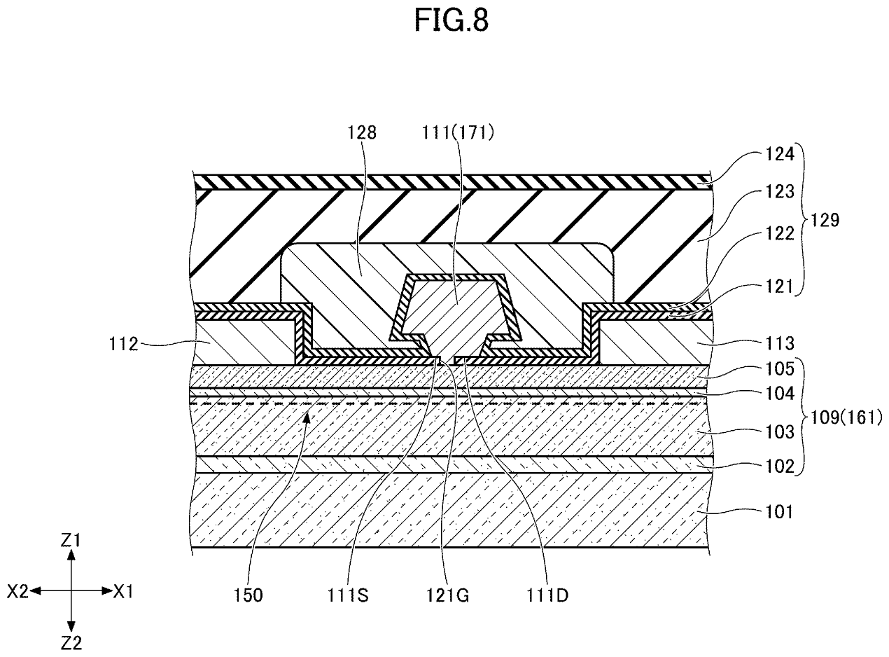

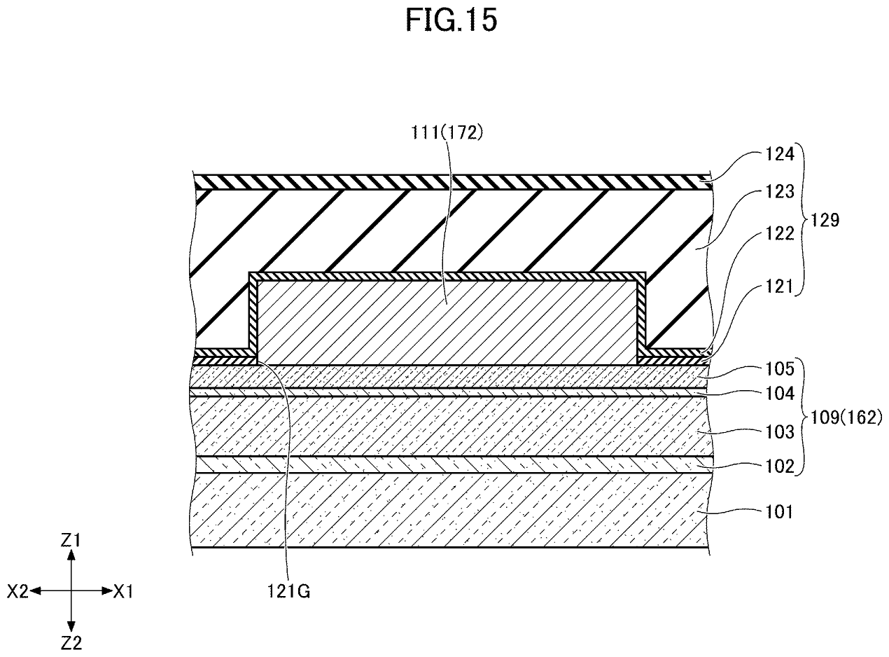

Then, as illustrated in FIG. 8 and FIG. 15, a low permittivity film 123 is formed on the insulating film 122. The low permittivity film 123 is formed to cover the sacrificial layer 128. Then, an insulating film 124 is formed on the low permittivity film 123. A multilayer insulating film 129 composed of the passivation film 121, the insulating film 122, the low permittivity film 123, and the insulating film 124 is obtained.

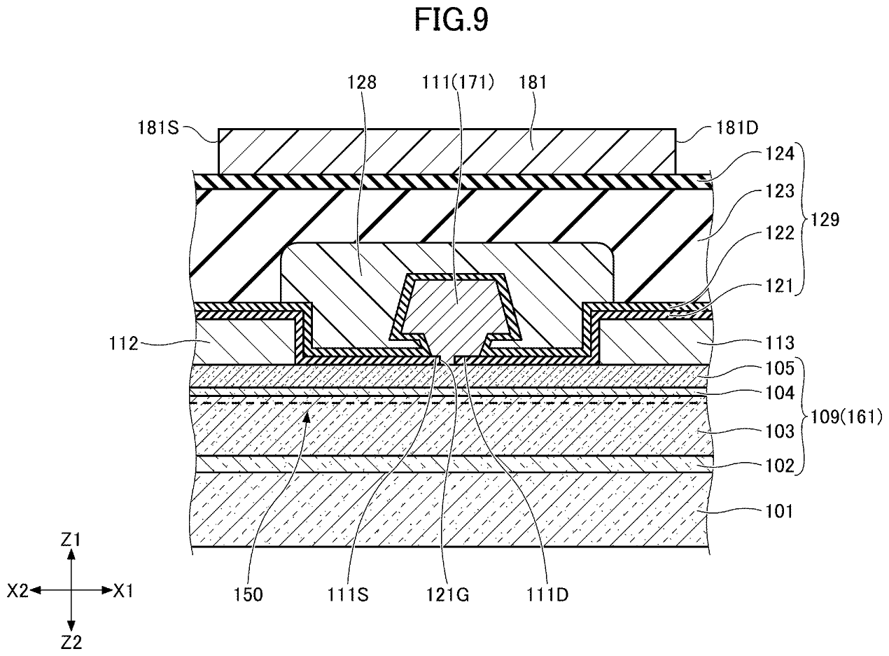

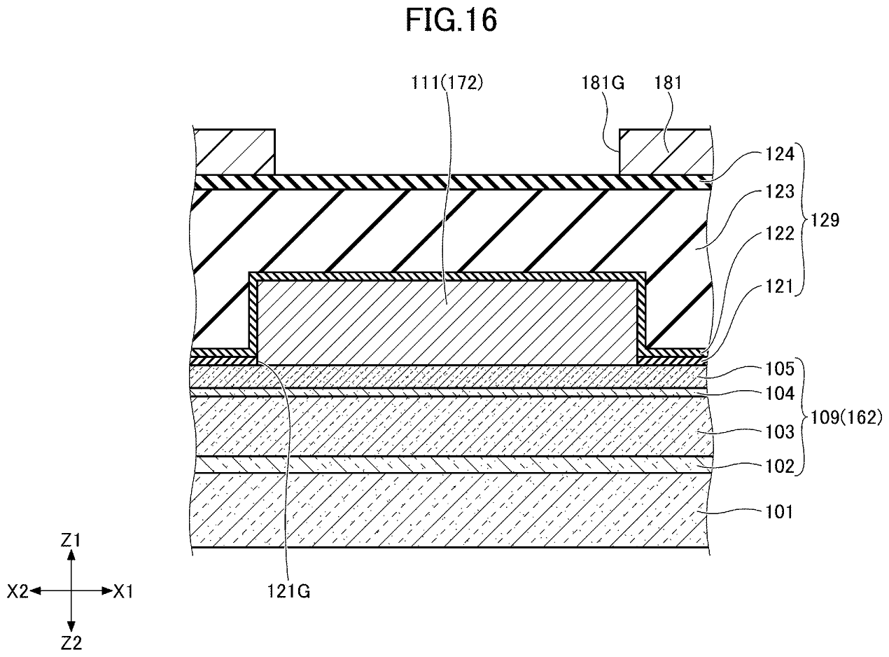

Subsequently, a resist pattern 181 is formed on the insulating film 124 as illustrated in FIG. 9 and FIG. 16. The resist pattern 181 includes an opening 181S in a portion forming an opening 129S, an opening 181D in a portion forming an opening 129D, and an opening 181G in a portion forming an opening 129G.

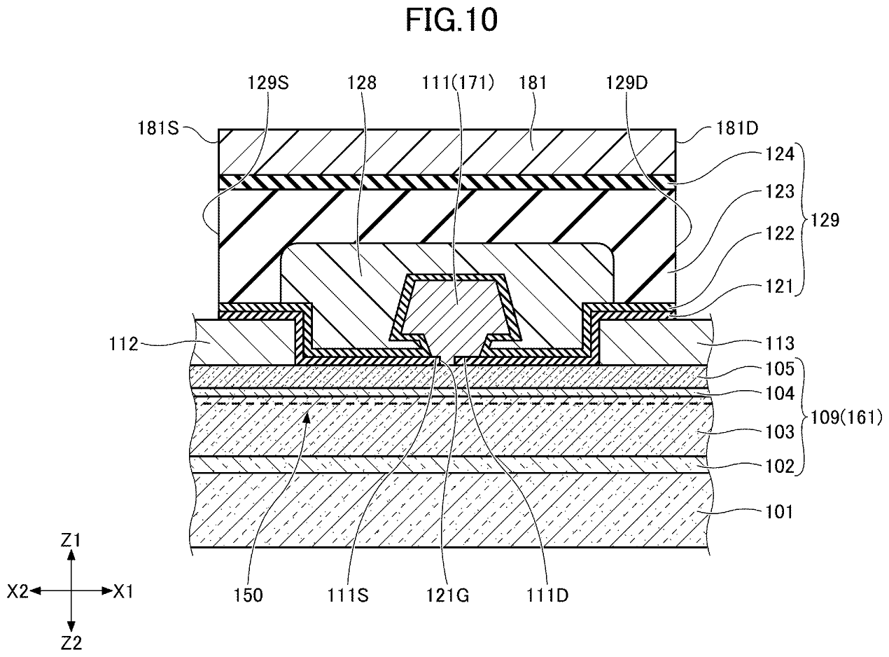

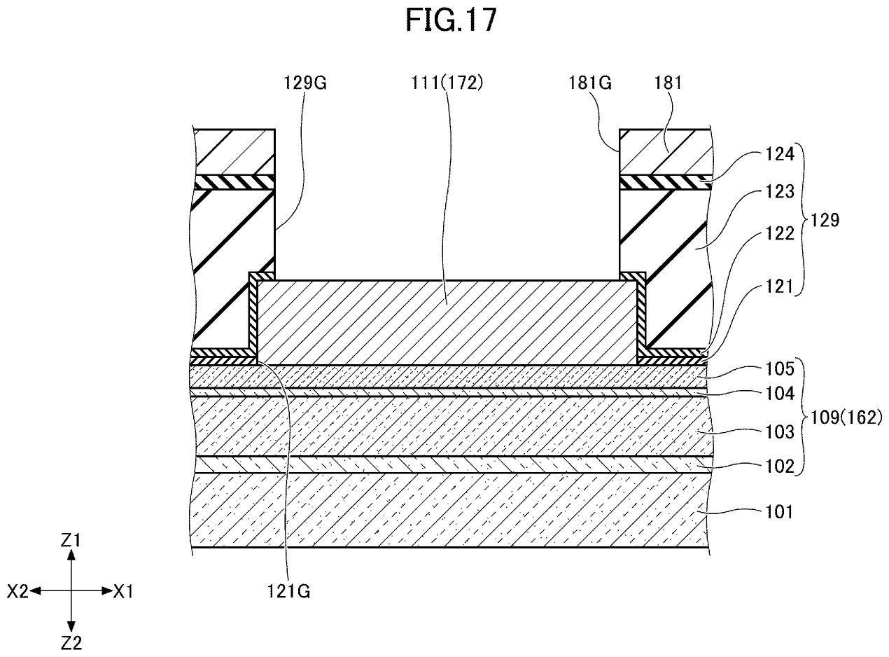

Then, as illustrated in FIG. 10 and FIG. 17, the openings 129S, 129D, and 129G are formed by removing the exposed portions from the resist pattern 181 of the multilayer insulating film 129 by etching.

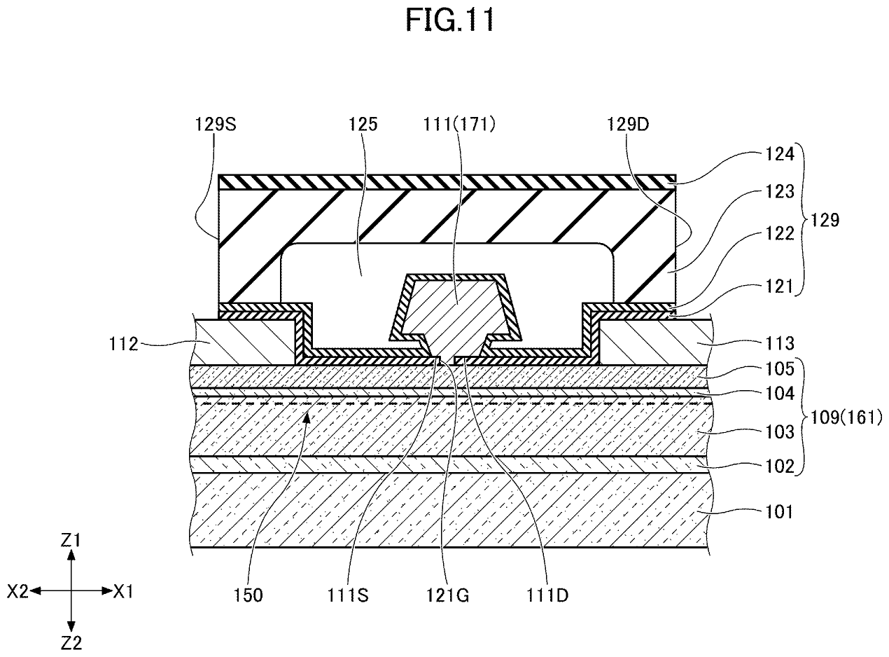

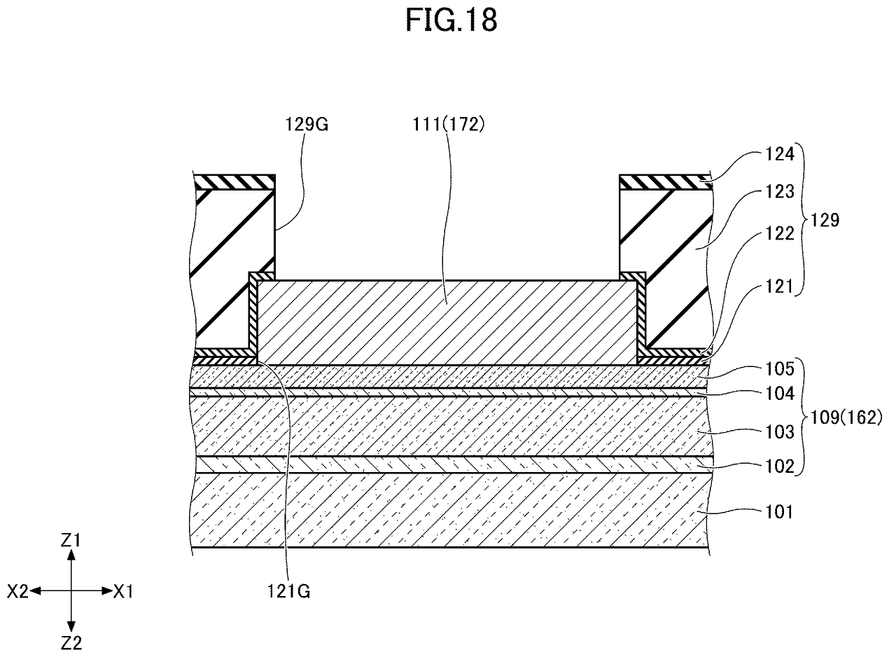

Then, as illustrated in FIG. 11 and FIG. 18, the resist pattern 181 and the sacrificial layer 128 are removed. The resist pattern 181 may be removed before the sacrificial layer 128, or the sacrificial layer 128 may be removed before the resist pattern 181.

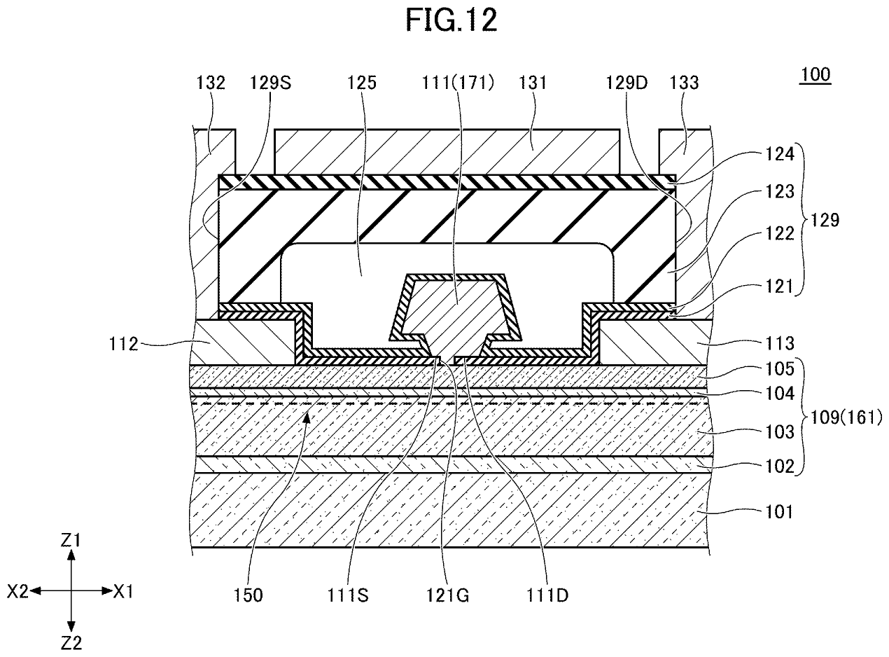

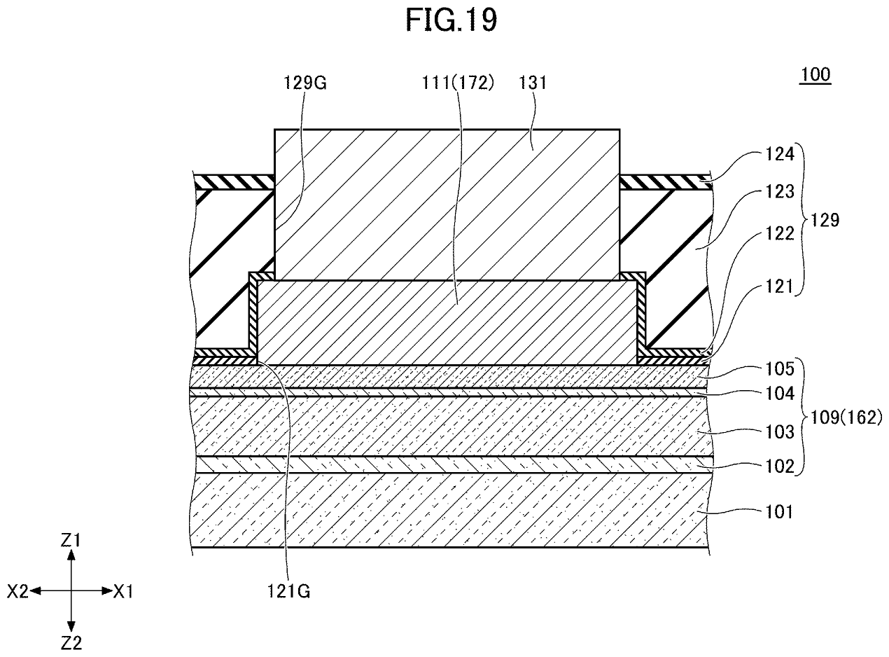

Subsequently, metal films 131, 132, and 133 are formed as illustrated in FIG. 12 and FIG. 19. In the formation of the metal films 131, 132, and 133, a seed layer is formed over the entire upper surface and a resist pattern is formed over the seed layer. The resist pattern includes an opening in a portion where the metal film 131 is formed, an opening in a portion where the metal film 132 is formed, and an opening in a portion where the metal film 133 is formed. Then, a plating layer is formed in these openings. Then, the resist pattern is removed, and the seed layer covered with the resist pattern is removed by milling or the like. The metal films 131, 132, and 133 may be formed simultaneously, the metal film 131 may be formed before metal films 132, and 133, or the metal films 132, and 133 may be formed before metal film 131.

In this manner, the semiconductor device 100 according to the first embodiment may be manufactured.

In the semiconductor device 100, the region where the 2DEG 150 exists functions as a channel, and the potential of the channel is controlled by the gate electrode 111. A control signal (high-frequency signal) is input from the gate pad to the gate electrode 111 through the metal film 131. In this embodiment, the gate electrode 111 includes two second regions 172 having the first region 171 interposed between the two second regions 172, and the metal film 131 is in contact with the two second regions 172. Therefore, high-frequency signals are input to the first region 171 from its both ends. Therefore, the phase shift of the high-frequency signal in the gate electrode 111 is reduced, and the adverse effect of the electrical resistance of the gate electrode 111 on the high-frequency signal can be reduced. That is, according to the first embodiment, excellent high-frequency characteristics can be obtained. For example, the maximum oscillation frequency can be improved. For example, the gain and efficiency can be improved for high-frequency signals in the sub-terahertz band with a frequency of 100 GHz or more.

Since the second region 172 is provided above the inactive region 162, the second region 172 is away from the source electrode 112 and the drain electrode 113. Therefore, even when the second region 172 is formed widely, the parasitic capacitance between the gate electrode 111 and the metal film 131 and the source electrode 112 and the drain electrode 113 can be kept low. Since the second region 172 is wide, the aspect ratio of the opening 129G can be kept small, and the opening 129G can be formed with high precision.

Furthermore, the metal film 131 is supported mainly by the low permittivity film 123, and the insulating film 124. Therefore, good mechanical strength can be ensured.

The gate opening 121G may be formed on the active region 161, and the inactive region 162 of the semiconductor layer 109 may be covered by the passivation film 121. That is, the second region 172 of the gate electrode 111 need not be in contact with the inactive region 162, but may be formed on the passivation film 121.

### Second Embodiment

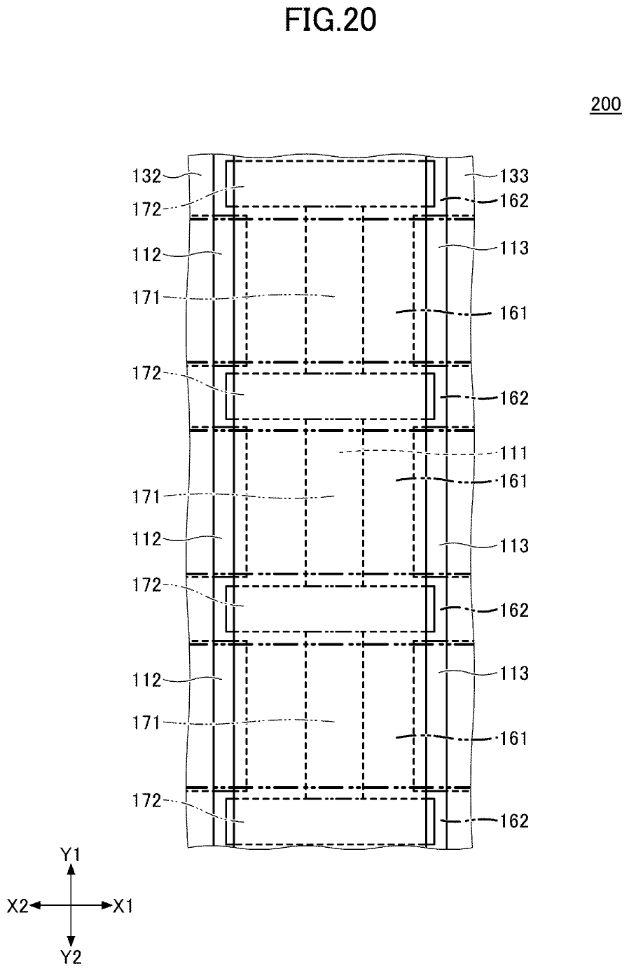

A second embodiment will be described. The second embodiment differs from the first embodiment mainly in the layout of active and inactive regions. FIG. 20 is a diagram illustrating a layout of electrodes and metal films in the semiconductor device according to the second embodiment.

In the semiconductor device 200 according to the second embodiment, as illustrated in FIG. 20, multiple active regions 161 are arranged parallel to each other in the Y1-Y2 direction. Then, inactive regions 162 are each formed between the adjacent active regions 161. The gate electrode 111 includes a first region 171 for each active region 161. Also, second regions 172 are each formed between adjacent first regions 171.

Other configurations are the same as in the first embodiment.

In the second embodiment, as in the first embodiment, the adverse effect of the electrical resistance of the gate electrode 111 on the high-frequency signal can be reduced, and excellent high-frequency characteristics can be obtained. In addition, the opening 129G can be formed with high precision.

Semiconductor devices can be used, for example, in base stations for cellular communication, communication devices for radio astronomy, and communication devices for satellite communication.

Although the preferred embodiments have been described in detail above, the present invention is not limited to the above described embodiments, and various modifications and substitutions can be made to the above described embodiments without deviating from the scope of claims.

According to the present disclosure, it is possible to reduce an adverse effect of the electrical resistance of a gate electrode on the high-frequency signals.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiment(s) of the present inventions have been described in detail, it should be understood that the various changes, substitutions, and alterations could be made hereto without departing from the spirit and scope of the invention.

What is claimed is:

1. A semiconductor device comprising:
a semiconductor layer including an electron transit layer and an electron supply layer;
a gate electrode, a source electrode and a drain electrode, the gate electrode, the source electrode and the drain electrode being disposed on the semiconductor layer; and
a metal film connected to the gate electrode,
wherein the semiconductor layer includes an active region, and an inactive region surrounding the active region in plan view,
wherein the gate electrode includes, in plan view, a first region overlapping the active region, and two second regions having the first region interposed therebetween, the two second regions both overlapping the inactive region, and
wherein the metal film contacts the two second regions.

2. The semiconductor device as claimed in claim 1, further comprising:
an insulating film supporting the metal film.

3. The semiconductor device as claimed in claim 2, wherein the insulating film includes a low permittivity film with a relative permittivity of 3.0 or less.

4. The semiconductor device as claimed in claim 3, wherein a cavity exists between the gate electrode and the low permittivity film.

5. The semiconductor device as claimed in claim 1, wherein in plan view, a dimension of each of the second regions in a direction in which the source electrode and the drain electrode are aligned is 2 μm or more.

6. The semiconductor device as claimed in claim 1, wherein in plan view, in a direction in which the source electrode and the drain electrode are aligned, a dimension of the first region is smaller than a dimension of each of the second regions.

7. The semiconductor device as claimed in claim 1, wherein electrical resistance of the metal film is lower than electrical resistance of the first region.

8. The semiconductor device as claimed in claim 1,
wherein the semiconductor layer includes a plurality of the active regions,
wherein the gate electrode includes the first region for each of the active regions, and
wherein the second region is between two adjacent first regions.

9. The semiconductor device as claimed in claim 1, further comprising:
a passivation film covering the semiconductor layer and having a gate opening,
wherein the gate electrode makes Schottky contact with the semiconductor layer through the gate opening,
wherein the gate electrode includes
a first surface that is in contact with an upper surface of the passivation film at a position closer to the source electrode than is the gate opening, and
a second surface that is in contact with the upper surface of the passivation film at a position closer to the drain electrode than is the gate opening, and
wherein in plan view, an end of the second surface closer to the drain electrode is farther from the gate opening than an end of the first surface closer to the source electrode.

10. A method of manufacturing a semiconductor device, the method comprising:
forming a semiconductor layer including an electron transit layer and an electron supply layer;
forming a gate electrode, a source electrode and a drain electrode on the semiconductor layer; and
forming a metal film connected to the gate electrode,
wherein the semiconductor layer includes an active region, and an inactive region surrounding the active region in plan view,
wherein the gate electrode includes, in plan view, a first region overlapping the active region, and two second regions having the first region interposed therebetween, the two second regions both overlapping the inactive region, and
wherein the metal film contacts the two second regions.
